(19) United States
(12) Patent Application Publication
(10) Pub. No.: US 2013/0169129 A1
(43) Pub. Date: Jul. 4, 2013

(54) COMPUTER ENCLOSURE

(71) Applicants: CHUNG CHAI, New Taipei (TW); DA-LONG SUN, Wuhan (CN); SHENG-HE LI, Wuhan (CN); HAI HUANG, Wuhan (CN)

(72) Inventors: CHUNG CHAI, New Taipei (TW); DA-LONG SUN, Wuhan (CN); SHENG-HE LI, Wuhan (CN); HAI HUANG, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/688,424

(22) Filed: Nov. 29, 2012

(30) Foreign Application Priority Data
Dec. 30, 2011 (CN) 201110453260.0

(51) Int. Cl. H05K 5/00

(52) U.S. Cl. CPC H05K 5/0013
USPC 312/223.2

(57) ABSTRACT

A computer enclosure includes an enclosure body, a cover panel, and a securing member. The enclosure body comprises a mounting panel. The mounting panel comprises a mounting panel body and a securing tab extending, at an angle, from the mounting panel body, the securing tab defines a securing hole. The cover panel defines an opening. The securing member comprises a securing portion secured to the cover panel, an engaging portion extending from the securing portion, and a handling portion extending from the securing portion. The engaging portion engages with the securing hole. The handling portion is exposed out of the cover panel via the opening. The handling portion is pressed inward via the opening to resist a free end of the securing tab and enable the securing tab to be deformed, thereby driving the securing hole to disengage from the engaging portion.

### BACKGROUND

1. Technical Field

The disclosure generally relates to computer enclosures, especially, to a computer enclosure with a cover panel.

2. Description of Related Art

A computer enclosure usually includes a chassis, a front panel, and two side panels. The front panel is attached to the chassis. A plurality of screws is provided to assemble the side panels with the front panel. A screwdriver is required in the assembly process. An improved computer enclosure with a side panel clip fastening configuration includes clip fasteners securing with slots of the computer enclosure, for assembling two side panels to the computer enclosure from an outer side thereof. The clip fasteners can be rotated on the side panels to engage or disengage with or from the slots of the computer enclosure, thereby assembling or disassembling the side panels. However, the clip fasteners have a complicated configuration and are not easy to use. Furthermore, having the clip fasteners on the outside of the side panels is unattractive.

Thus, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a computer enclosure.

FIG. 2 is a partial, enlarged view of FIG. 1.

FIG. 3 is an isometric view of a securing member of FIG. 1.

FIG. 4 is an assembled view of FIG. 1.

FIG. 5 is a partial, cutaway view of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

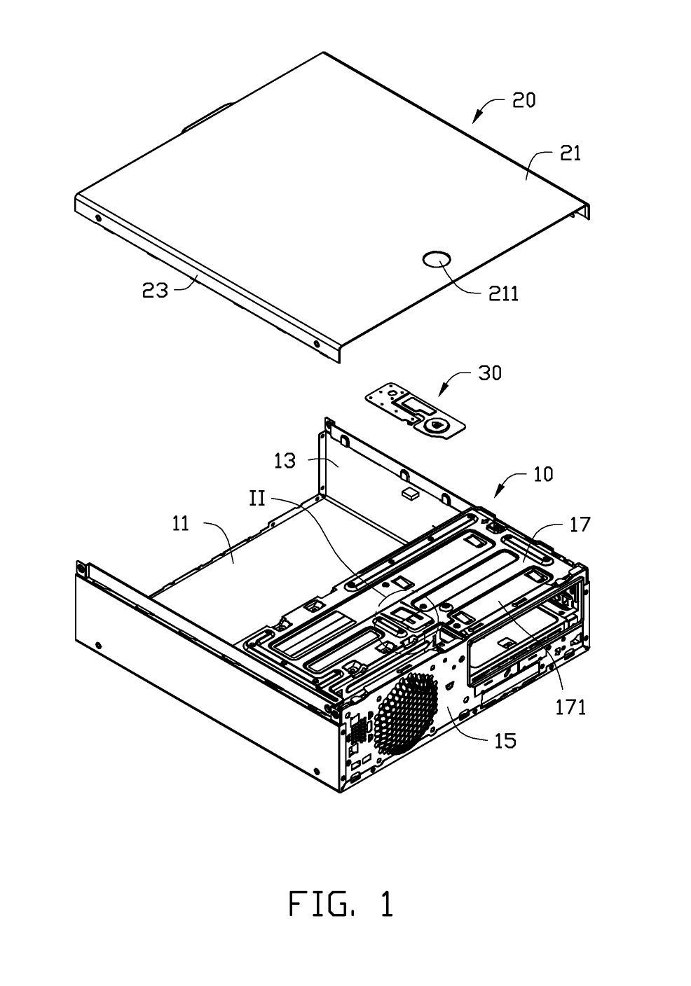

FIG. 1 shows one embodiment of a computer enclosure. The computer enclosure includes an enclosure body 10, a cover panel 20, and a securing member 30 secured to the cover panel 20.

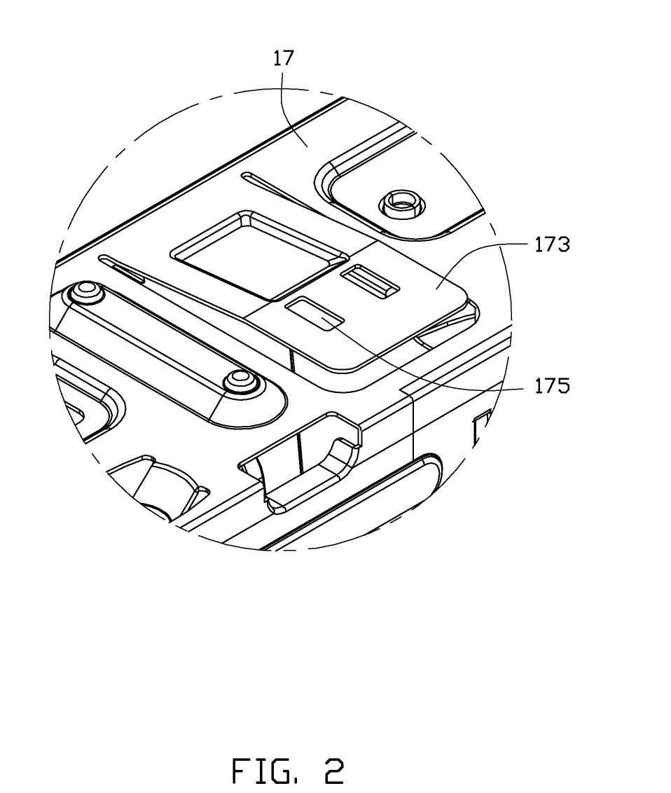

Referring to FIG. 2, the enclosure body 10 includes a bottom panel 11, two side panels 13 extending from the bottom panel 11, a front panel 15 extending from the bottom panel 11, and a mounting panel 17 connected between the two side panels 13. The two side panels 13 are substantially parallel to each other and are substantially perpendicular to the bottom panel 11. The front panel 15 is substantially perpendicular to the two side panels 13 and the bottom panel 11. The mounting panel 17 includes a mounting panel body 171 that is substantially parallel to the bottom panel 11 and a securing tab 173 extending from the mounting panel body 171. The securing tab 173 defines two securing holes 175. There is an acute angle between the securing tab 173 and the mounting panel body 171.

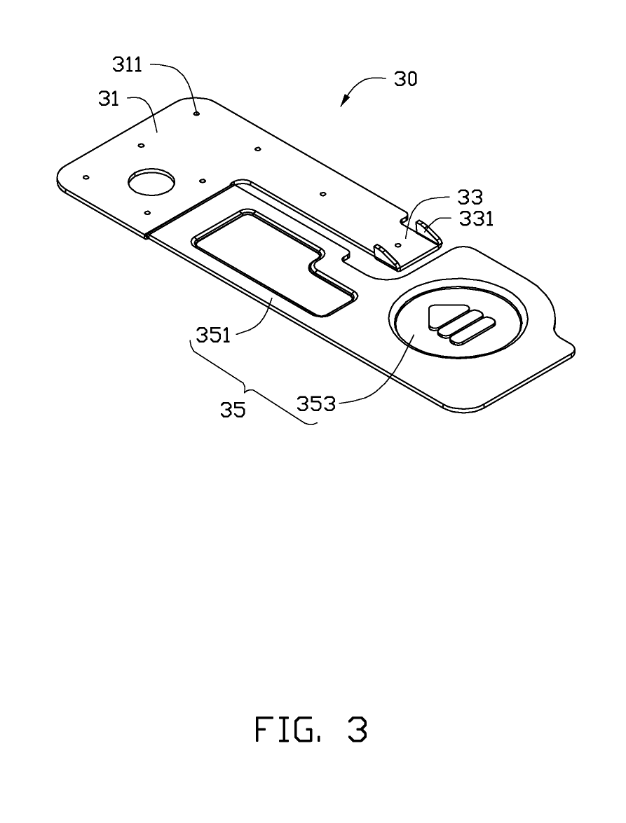

Referring to FIGS. 1 to 3, the securing member 30 includes a securing portion 31, an engaging portion 33 extending from the securing portion 31, and a handling portion 35 extending from the securing portion 31. The securing portion 31 includes a plurality of securing protrusions 311. The engaging portion 33 includes two hooks 331 corresponding to the securing holes 175. The handling portion 35 includes a resilient arm 351 connected to the securing portion 31 and a pressing portion 353 extending from the resilient arm 351.

The cover panel 20 includes a cover panel body 21 that is substantially parallel to the bottom panel 11 and two flanges 23 extending from opposite sides of the cover panel body 21. The two flanges 23 are used for covering the outer sides of the two side panels 13. The cover panel body 21 defines an opening 211 corresponding to the pressing portion 353 of the securing member 30.

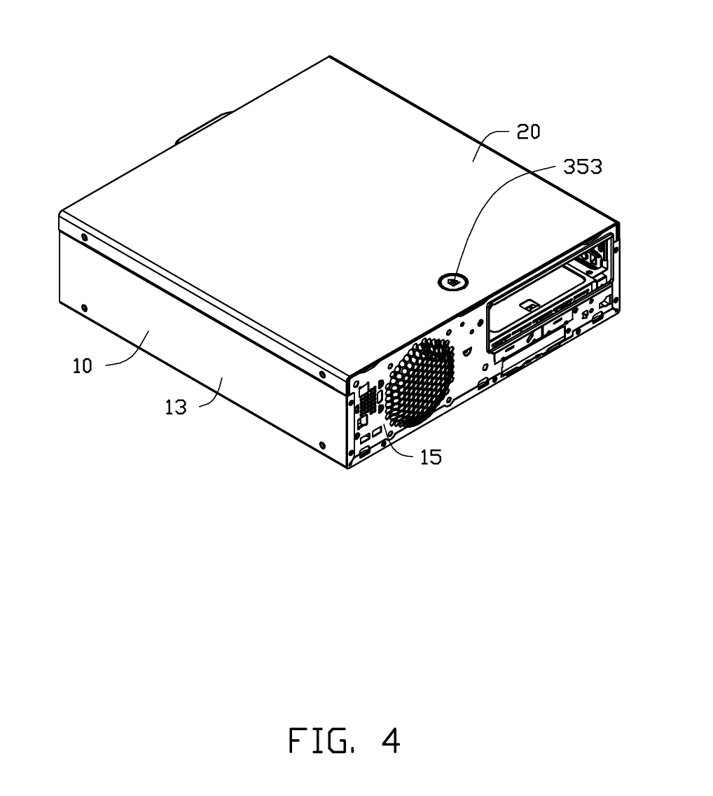

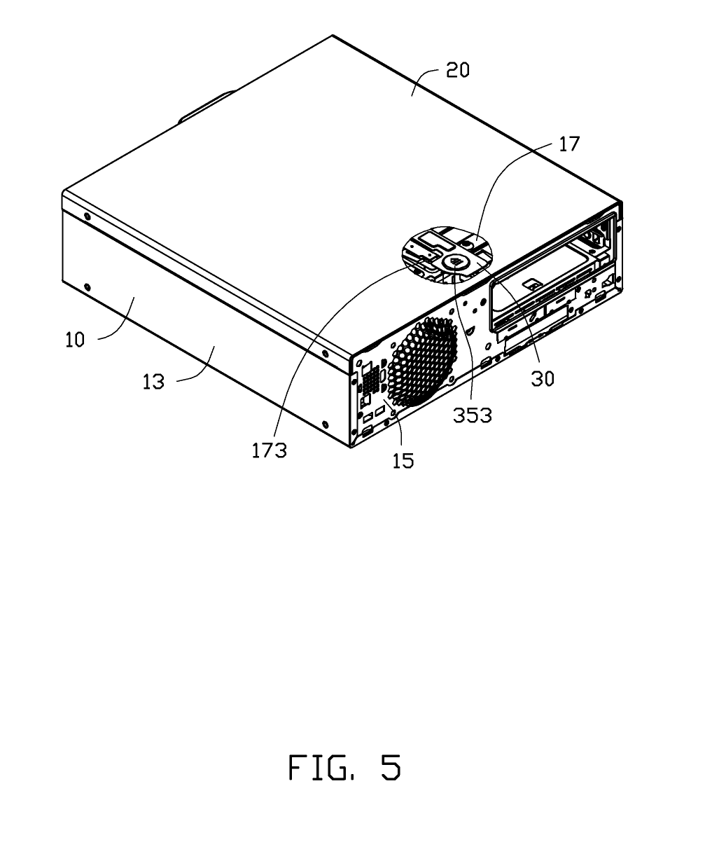

Referring to FIGS. 4 and 5, in assembly, the pressing portion 353 of the securing member 30 corresponds to the opening 211 of the cover panel. The securing member 30 is secured to the inner side of the cover panel body 21, via welding the securing protrusions 311, to the inner side of the cover panel body 21. The cover panel 20 is placed on the enclosure body 10 to enable the two side panels 13 are located between the two flanges 23 of the cover panel 20. The cover panel 20 is pushed towards the front panel 15 of the enclosure body 10. The hooks 331 of the securing member 30 resist the securing tab 173 to enable the securing tab 173 to be deformed. The cover panel 20 is pushed continually until the hooks 331 correspond to the securing holes 175. At this time, the securing tab 173 rebounds to enable the securing holes 175 to engage with the hooks 331, thereby preventing the cover panel 20 from moving along a direction substantially parallel to the bottom panel 11.

In disassembly, the pressing portion 353 is pressed inward, via the opening 211, to enable the resilient arm 351 of the securing member 30 to be deformed. The pressing portion 353 resists the free end of the securing tab 173, to enable the securing tab 173 to be deformed, thereby driving the securing holes 175 of the securing tab 173 to disengage from the hooks 331. The cover panel 20 is thus removed out of the enclosure body 10.

It is to be understood, however, that even though numerous characteristics and advantages have been set forth in the foregoing description of embodiments, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A computer enclosure, comprising:
an enclosure body, the enclosure body comprises a mounting panel, the mounting panel comprises a mounting panel body and a securing tab extending, at an angle, from the mounting panel body, and the securing tab defines a securing hole;
a cover panel, and the cover panel defines an opening; and
a securing member, the securing member comprises a securing portion secured to the cover panel, an engaging portion extending from the securing portion, and a handling portion extending from the securing portion; the engaging portion engages the securing hole; the handling portion is exposed out of the cover panel via the opening; and the handling portion is configured to be pressed inward via the opening, to resist a free end of the securing tab and enable the securing tab to be deformed, thereby driving the securing hole to disengage from the engaging portion.

2. The computer enclosure of claim 1, wherein the enclosure body comprises a bottom panel and two side panels extending from the bottom panel; the two side panels are substantially perpendicular to the bottom panel; the cover panel is mounted to the two side panels; the mounting panel body is substantially parallel to the bottom panel; and the engaging portion engages the securing hole to prevent the cover panel from moving along a direction substantially parallel to the bottom panel.

3. The computer enclosure of claim 2, wherein the cover panel comprises a cover panel body that is substantially parallel to the bottom panel and two flanges extending from opposite sides of the cover panel body, and the two flanges contact the two side panels.

4. The computer enclosure of claim 1, wherein the handling portion comprises a resilient arm, extending from the securing portion, and a pressing portion, extending from the resilient arm, and the pressing portion is located in the opening.

5. The computer enclosure of claim 1, wherein the securing portion comprises a plurality of securing protrusions for welding the securing member to an inner side of the cover panel.

6. The computer enclosure of claim 1, wherein the engaging portion comprises a hook engaging with the securing hole.

7. A computer enclosure, comprising:
an enclosure body, the enclosure body comprises a mounting panel, the mounting panel comprises a mounting panel body and a securing tab extending, at an angle, from the mounting panel body, and the securing tab defines a securing hole;
a cover panel; and
a securing member, the securing member comprises a securing portion secured to the cover panel and an engaging portion extending from the securing portion; the engaging portion is configured to resist the securing tab to be deformed to be aligned with the securing hole when the cover panel is mounted to the enclosure body; and the securing tab is configured to rebound to enable the securing hole to engage with the engaging portion.

8. The computer enclosure of claim 7, wherein the enclosure body comprises a bottom panel and two side panels extending from the bottom panel; the two side panels are substantially perpendicular to the bottom panel; the cover panel is mounted to the two side panels; the mounting panel body is substantially parallel to the bottom panel; and the engaging portion engages with the securing hole to prevent the cover panel from moving along a direction substantially parallel to the bottom panel.

9. The computer enclosure of claim 8, wherein the cover panel comprises a cover panel body substantially parallel to the bottom panel and two flanges extending from opposite sides of the cover panel body, and the two flanges contact the two side panels.

10. The computer enclosure of claim 7, wherein the cover panel defines an opening; the securing member comprises a handling portion extending from the securing portion; the handling portion comprises a resilient arm extending from the securing portion and a pressing portion extending from the resilient arm; the pressing portion is located in the opening; and the pressing portion is configured to be pressed inward via the opening to resist a free end of the securing tab to enable the securing tab to be deformed, thereby driving the securing hole to disengage from the engaging portion.

11. The computer enclosure of claim 7, wherein the securing portion comprises a plurality of securing protrusions for welding the securing member to an inner side of the cover panel.

12. The computer enclosure of claim 7, wherein the engaging portion comprises a hook engaging with the securing hole.
